(19) United States
(12) Patent Application Publication
(10) Pub. No.: US 2007/0228491 A1
(43) Pub. Date: Oct. 4, 2007

(54) Tunneling transistor with sublithographic channel

(75) Inventor: Leonard Forbes, Corvallis, OR (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/397,406

(22) Filed: Apr. 4, 2006

(51) Int. Cl. H01L 29/76

(52) U.S. Cl. 257/401

(57) ABSTRACT

Disclosed herein are vertical tunneling transistors with gates that surround transistor bodies that have a width dimension less than a photolithographic dimension. These thin tunneling transistors with surrounding gates are used to obtain low sub-threshold leakage. Various embodiments provide sublithographic bodies by growing a crystalline nanofin from an amorphous structure formed on a substrate, by etching a crystalline substrate to define a crystalline nanofin from the crystalline substrate, or by growing a crystalline nanowire from an amorphous structure formed on the substrate. Other aspects and embodiments are provided herein.

### CROSS REFERENCE TO RELATED APPLICATIONS

This application is related to the following commonly assigned U.S. patent applications which are filed on even date herewith and are herein incorporated by reference in their entirety: “Nanowire Transistor With Surrounding Gate,” U.S. application Ser. No. ______, filed on ______ (Attorney Docket No. 1303.167US1); “Grown Nanofin Transistors,” U.S. application Ser. No. ______, filed on ______ Attorney Docket No. 1303.168US1); “Etched Nanofin Transistors,” U.S. application Ser. No. ______, filed on ______ (Attorney Docket No. 1303.170US1); and “DRAM With Nanofin Transistors,” U.S. application Ser. No. ______, filed on ______ (Attorney Docket No. 1303.171US1).

This application is also related to the following commonly assigned U.S. patent applications which are herein incorporated by reference in their entirety: “Vertical Tunneling Nano-Wire Transistor,” U.S. application Ser. No. 11/210,374, filed on Aug. 25, 2004; “Ultra-Thin Body Vertical Tunneling Transistor,” U.S. application Ser. No. 11/215,468, filed on Aug. 29, 2005; and “DRAM Tunneling Access Transistor,” U.S. application Ser. No. 11/219,085, filed Aug. 29, 2005.

### TECHNICAL FIELD

This disclosure relates generally to semiconductor devices, and more particularly, to tunneling transistors with sublithographic channels.

### BACKGROUND

The semiconductor industry has a market driven need to reduce the size of devices, such as transistors, and increase the device density on a substrate. Some product goals include lower power consumption, higher performance, and smaller sizes. Transistor lengths have become so small that current continues to flow when they are turned off, draining batteries and affecting performance. When the gate-source voltage of a metal oxide semiconductor (MOS) transistor is less than its voltage threshold, it is in the sub-threshold region. This is characterized by an exponential change in drain current with the gate-source voltage. As technology scales, sub-threshold leakage currents can grow exponentially and become an increasingly large component of total power dissipation. This is of great concern to designers of handheld or portable devices where battery life is important, so minimizing power dissipation while achieving satisfactory performance is an increasingly important goal. Leakage current is a significant issue in DRAM. circuits as it reduces the charge storage retention time on the capacitor cells.

FIG. 1 illustrates general trends and relationships for a variety of device parameters with scaling by a factor k. Junction depths, for example, should be much less than the channel length in conventional transistor structures. Thus, with reference to the transistor 100 illustrated in FIG. 1, the junctions depths 101 should be on the order of a few hundred Angstroms for channels lengths 102 that are approximately 1000 Å long. Such shallow junctions are difficult to form by conventional implantation and diffusion techniques. Extremely high levels of channel doping are required to suppress short-channel effects such as drain induced barrier lowering, threshold voltage roll off, and sub-threshold conduction. These extremely high doping levels result in increased leakage and reduced carrier mobility. The threshold voltage magnitudes are small to achieve significant overdrive and reasonable switching speeds. However, as illustrated in FIG. 2, the small threshold results in a relatively large sub-threshold leakage current. Thus, the expected improved performance attributed to a shorter channel is negated by the lower carrier mobility and higher leakage attributed to the higher doping.

FIG. 3 illustrates a comparison between an ideal sub-threshold slope of 60 mV/decade for a conventional planar CMOS transistor and a sub-threshold slope on the order of 120 mV/decade to 80 mV/decade for a conventional planar transistor structure with short channel effects. This figure reflects the difficulty in controlling and reducing sub-threshold leakage currents in conventional nanoscale planar CMOS transistor technology. The problem is exasperated by the lower power supply voltages used in nanoscale CMOS circuits which is now of the order 2.5 V and projected to become even lower into the range of 1.2 V. The sub-threshold leakage current should be at least eight orders of magnitude or eight decades below the transistor current levels when the transistor is turned on in order to provide good Ion/Ioff ratios; but a 1.2 V power supply does not provide enough voltage swing for a conventional planar device to provide both high current and low sub-threshold leakage. Turning the transistor on requires some significant voltage over drive above the threshold voltage VT, and turning the transistor sub-threshold leakage off requires several multiples of the threshold voltage slope, illustrated as about 100 mV/decade in FIG. 3.

Some proposed designs to address this problem use transistors with ultra-thin bodies, or transistors where the surface space charge region scales as other transistor dimensions scale down. Dual-gated or double-gated transistor structures also have been proposed to scale down transistors. As commonly used in the industry, “dual-gate” refers to a transistor with a front gate and a back gate which can be driven with separate and independent voltages, and “double-gated” refers to structures where both gates are driven when the same potential. Gate body connected transistors provide a dynamic or changing threshold voltage, providing a low threshold when the transistor is on and a high threshold when the transistor is off. An example of a double-gated device structure is the FinFET. “TriGate” structures and surrounding gate structures have also been proposed. In the “TriGate” structure, the gate is on three sides of the channel. In the surrounding gate structure, the gate surrounds or encircles the transistor channel. The surrounding gate structure provides desirable control over the transistor channel, but the structure has been difficult to realize in practice.

FIG. 4 illustrates a dual-gated MOSFET with a drain, a source, and front and back gates separated from a semiconductor body by gate insulators, and also illustrates an electric field generated by the drain. Some characteristics of the dual-gated and/or double-gated MOSFET are better than the conventional bulk silicon MOSFETs, because compared to a single gate the two gates better screen the electric field generated by the drain electrode from the source-end of the channel. A surrounding gate further screens the electric field generated by the drain electrode from the source. FIG. 5 generally illustrates the improved sub-threshold characteristics of dual gate, double-gate, or surrounding gate MOSFETs in comparison to the sub-threshold characteristics of conventional bulk silicon MOSFETs. The sub-threshold current is reduced more quickly when the dual-gate and/or double gate MOSFET turns off.

MOSFETs with sublithographic channel dimensions, such as a FinFET, can have a sub-threshold slope of 60 mV/decade, which is smaller than the sub-threshold slope associated with larger, conventional planar MOSFETs. There is, however, still a need for a new device structure which has a much reduced sub-threshold leakage.

### SUMMARY

Tunneling transistors can have a sub-threshold slope near zero. Disclosed herein are vertical tunneling transistors with gates that surround transistor bodies that have a width dimension less than a photolithographic dimension. These thin tunneling transistors with surrounding gates are used to obtain low sub-threshold leakage in CMOS circuits. Various embodiments provide sublithographic bodies by growing a crystalline nanofin from an amorphous structure formed on a substrate, by etching a crystalline substrate to define a crystalline nanofin from the crystalline substrate, or by growing a crystalline nanowire from an amorphous structure formed on the substrate. Various embodiments use sidewall spacer techniques to achieve the sublithographic dimension.

Various aspects relate to a transistor. Various transistor embodiments include a nanofin with a sublithographic cross-sectional width in a first direction and a cross-sectional width in a second direction orthogonal to the first direction that corresponds to a minimum feature size, a surrounding gate insulator around the nanofin, and a surrounding gate around and separated from the nanofin by the surrounding gate insulator. A first source/drain region of a first conductivity type at a bottom end of the nanofin and a second source/drain region of a second conductivity type at a top end of the nanofin define a vertically-oriented channel region between the first source/drain region and the second source/drain region. Various transistor embodiments include a crystalline pillar with at least one sublithographic cross-sectional dimension formed on a substrate surface, a surrounding gate insulator around the crystalline pillar, and a surrounding gate around and separated from the crystalline pillar by the surrounding gate insulator. The crystalline pillar is adapted to provide a vertically-oriented channel region between a first source/drain region of a first conductivity type and a second source/drain region of a second conductivity type.

Various aspects relate to a method of forming a transistor. According to various embodiments of the method, a nanofin is formed with a sublithographic cross-sectional width in a first direction and a cross-sectional width in a second direction orthogonal to the first direction that corresponds to a minimum feature size. A surrounding gate insulator is formed around the nanofin, and a surrounding gate is formed around and separated from the nanofin by the surrounding gate insulator. The nanofin is adapted to provide a vertically-oriented channel between a first source/drain region of a first conductivity type and a second source/drain region of a second conductivity type. Various embodiments form an amorphous semiconductor pillar on a substrate and recrystallize the semiconductor pillar to form the nanofin. Various embodiments etch trenches in a crystalline substrate to form the nanofin from the substrate.

According to various embodiments of the method, a crystalline pillar is formed with at least one sublithographic cross-sectional dimension, including forming an amorphous semiconductor pillar on a substrate and recrystallizing the semiconductor pillar to form the crystalline pillar. A surrounding gate insulator is formed around the crystalline pillar, and a surrounding gate is formed around and separated from the crystalline pillar by the surrounding gate insulator. The crystalline pillar is adapted to provide a vertically-oriented channel region between a first source/drain region of a first conductivity type and a second source/drain region of a second conductivity type.

These and other aspects, embodiments, advantages, and features will become apparent from the following description of the present subject matter and the referenced drawings.

### BRIEF DESCRIPTION OF THE DRAWINGS

FIG. 1 illustrates general trends and relationships for a variety of device parameters with scaling by a factor k.

FIG. 2 illustrates sub-threshold leakage in a conventional silicon MOSFET.

FIG. 3 illustrates a comparison between an ideal sub-threshold slope of 60 mV/decade for a conventional planar CMOS transistor and a sub-threshold slope on the order of 120 mV/decade to 80 mV/decade for a conventional planar transistor structure with short channel effects.

FIG. 4 illustrates a dual-gated MOSFET with a drain, a source, front and back gates separated from a semiconductor body by gate insulators, and an electric field generated by the drain.

FIG. 5 generally illustrates the improved sub-threshold characteristics of dual gate, double-gate, and surrounding gate MOSFETs in comparison to the sub-threshold characteristics of conventional bulk silicon MOSFETs.

FIG. 6 illustrates a transistor structure with a vertical sublithographic channel, a surrounding gate, and source/drain regions of the same conductivity type.

FIG. 7 illustrates a tunneling transistor with a vertical sublithographic channel, a surrounding gate, and source/drain regions of different conductivity types, according to various embodiments of the present subject matter.

FIG. 8 illustrates an energy band diagram of the electrical operation of the tunneling transistor of FIG. 7 when a transistor gate is not biased, according to various embodiments of the present subject matter.

FIG. 9 illustrates an energy band diagram of the electrical operation of the tunneling transistor of FIG. 7 when a transistor gate is biased, according to various embodiments of the present subject matter.

FIG. 10 illustrates a plot of drain current versus the gate-to-source voltage of the tunneling transistor of the tunneling transistor of FIG. 7, and illustrates the sub-threshold leakage current, according to various embodiments of the present subject matter.

FIGS. 11A-11H illustrate a process for growing a nanowire body to provide a vertical channel for a tunneling transistor, according to various embodiments of present subject matter.

FIGS. 12A-12L illustrate a process for growing a nanofin body to provide a vertical channel for a tunneling transistor, according to various embodiments of present subject matter.

FIGS. 13A-13L illustrate a process for etching a substrate to define a nanofin body to provide a vertical channel for a tunneling transistor, according to various embodiments of present subject matter.

FIG. 14 illustrates a method to form a tunneling nanofin transistor, according to various embodiments of the present subject matter.

FIG. 15 illustrates a method to grow a sublithographic transistor body for a tunneling transistor, according to various embodiments of the present subject matter.

FIG. 16 illustrates a top view of a layout of nanofins for an array of tunneling nanofin transistors, according to various embodiments of the present subject matter.

FIG. 17 illustrates a NOR gate logic circuit that includes tunneling transistors, according to various embodiments of the present subject matter.

FIG. 18 illustrates a NAND gate logic circuit that includes a tunneling transistor, according to various embodiments of the present subject matter.

FIG. 19 is a simplified block diagram of a high-level organization of various embodiments of a memory device according to various embodiments of the present subject matter.

FIG. 20 illustrates a diagram for an electronic system having one or more tunneling transistors, according to various embodiments.

FIG. 21 depicts a diagram of an embodiment of a system having a controller and a memory.

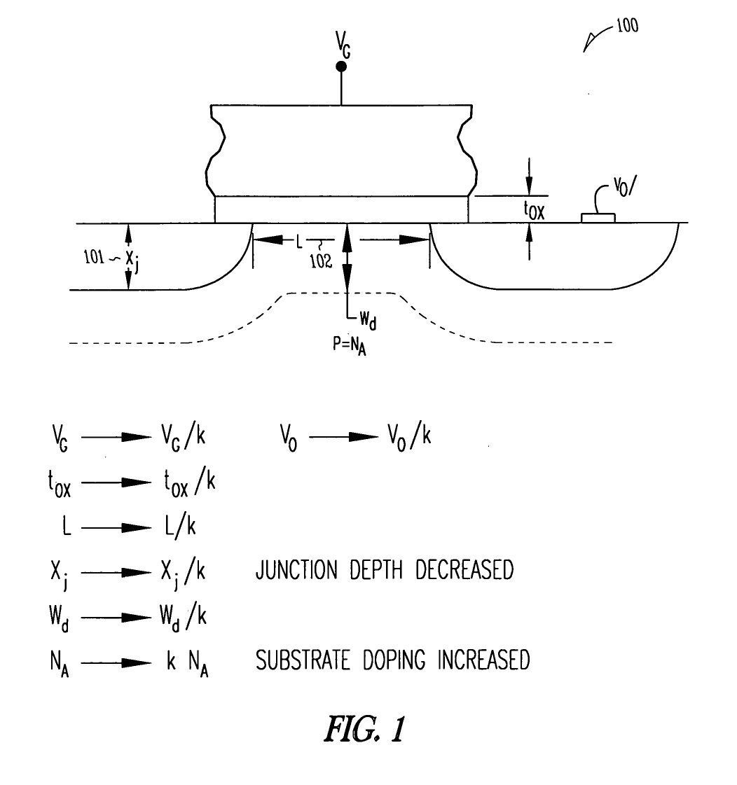

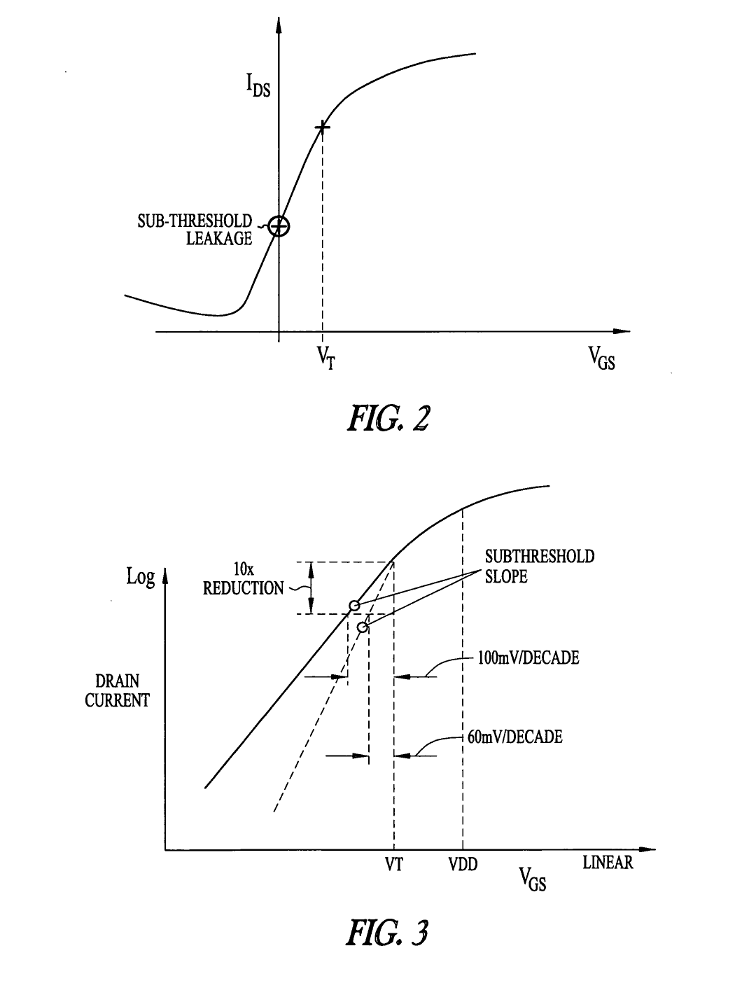

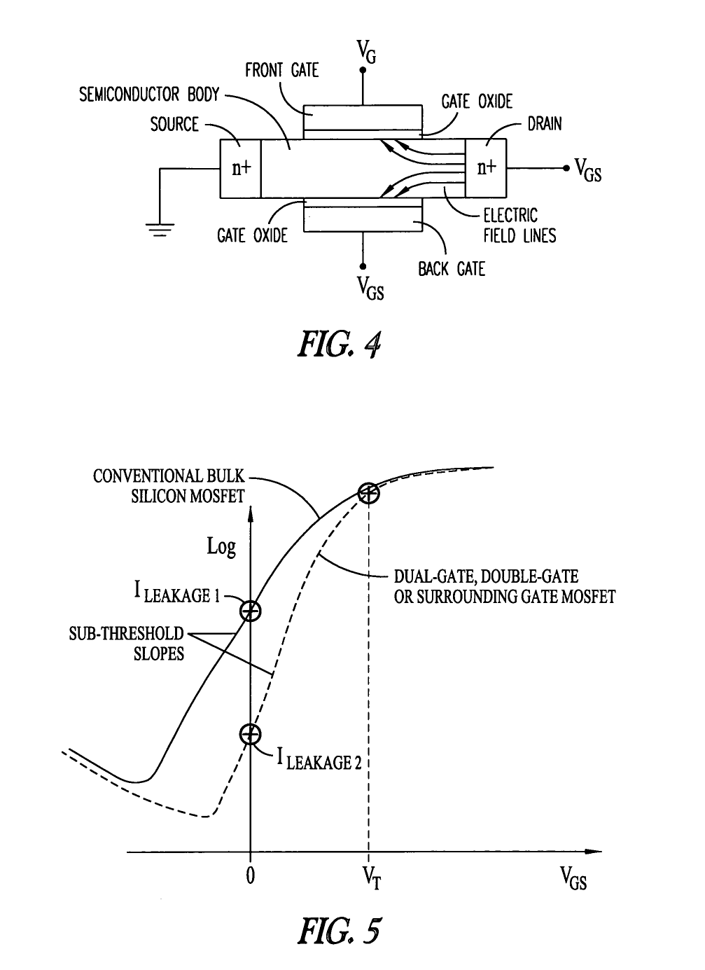

### DETAILED DESCRIPTION

The following detailed description refers to the accompanying drawings which show, by way of illustration, specific aspects and embodiments in which the present subject matter may be practiced. These embodiments are described in sufficient detail to enable those skilled in the art to practice the present subject matter. The various embodiments of the present subject matter are not necessarily mutually exclusive as aspects of one embodiment can be combined with aspects of another embodiment. Other embodiments may be utilized and structural, logical, and electrical changes may be made without departing from the scope of the present subject matter. In the following description, the terms “wafer” and “substrate” are interchangeably used to refer generally to any structure on which integrated circuits are formed, and also to such structures during various stages of integrated circuit fabrication. Both terms include doped and undoped semiconductors, epitaxial layers of a semiconductor on a supporting semiconductor or insulating material, combinations of such layers, as well as other such structures that are known in the art. The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side”, “higher”, “lower”, “over” and “under” are defined with respect to the conventional plane or surface being on the top surface of the wafer or substrate, regardless of the orientation of the wafer or substrate. The following detailed description is, therefore, not to be taken in a limiting sense, and the scope of the present invention is defined only by the appended claims, along with the full scope of equivalents to which such claims are entitled.

The present subject matter relates to tunneling transistors with surrounding gates and sublithographic channels. Various embodiments of the tunneling transistor structures and their method of formation are described below. The structures include grown nanowire tunneling transistors, grown nanofin tunneling transistors, and etched nanofin transistors. Also described below are a layout for a nanofin array, examples of CMOS logic circuits, and higher level devices and systems.

Tunneling Transistor

FIG. 6 illustrates a transistor structure 603 with a vertical sublithographic channel 604, a surrounding gate 605, and source/drain regions 606 and 607 of the same conductivity type. The transistor can be a nanofin transistor such as described in U.S. application Ser. Nos. ______ (Attorney Docket Nos. 1303.168US1 and 1303.170US1), or can be a nanowire transistor such as described in U.S. application Ser. No. ______ (Attorney Docket No. 1303.167US1). A surrounding gate 605 is around and separated from the body or channel 604 by a surrounding gate insulator 608. The substrate is doped to form a conductive line 609 in the substrate that is conductively connected to the bottom source/drain region 606.

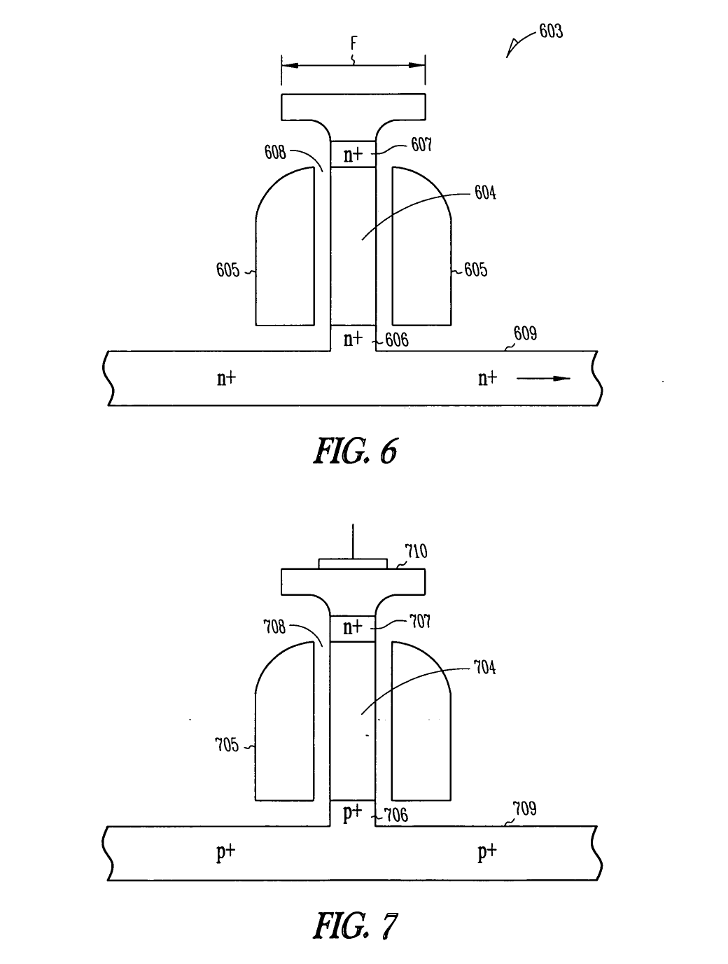

FIG. 7 illustrates a tunneling transistor with a vertical sublithographic channel, a surrounding gate, and source/drain regions of different conductivity types, according to various embodiments of the present subject matter. The illustrated embodiment is formed in a silicon substrate or N+ well. Alternate embodiments may use other conductivity doping for the substrate.

Instead of the conventional N+ source region formed in the substrate as in the transistor illustrated in FIG. 6, the first source/drain region 706 of the present subject matter is P+ doped. Additionally, the source wiring 709 that couples the first source/drain region 706 to other components in a circuit is also P+ doped.

A lightly doped, thin p-type body 704 is formed over the first source/drain region 706. In one embodiment, this is implemented in 0.1 micron technology such that the transistor has a height of approximately 100 nm and a thickness in the range of 25 to 50 nm. Alternate embodiments may use other heights and/or thickness ranges.

An N+ doped second source/drain region 707 is formed at the top of the silicon body 704. A contact 710 is formed on the second source/drain region 707 to allow connection of the transistor's second source/drain region to other components of an electronic circuit. This connection may be a metal or some other material.

A gate insulator layer 708 is formed around the thin body 709. The insulator can be an oxide or some other type of dielectric material. Some embodiments form the insulator by oxidizing the semiconductor body. For example, an embodiment performs a thermal oxidation process of a silicon pillar to provide a silicon oxide gate insulator around the pillar.

A control gate 705 is formed around the insulator layer 708. As is well known in the art, proper biasing of the control gate causes an N-channel to form in a channel region between the first and second source/drain regions 706 and 707.

The P+ first source/drain region can be implanted. Since the P+ doping is always lower than the N+, the tops of the pillars need not be masked, as they will remain N+. The resulting pillars have P+ regions under the sidewalls and an N+ region at the top. The pillars are thin and the P+ regions will diffuse and merge under the pillar. In an embodiment, the transistor structure has a grown or deposited gate insulator and a surrounding gate formed by a sidewall etch technique.

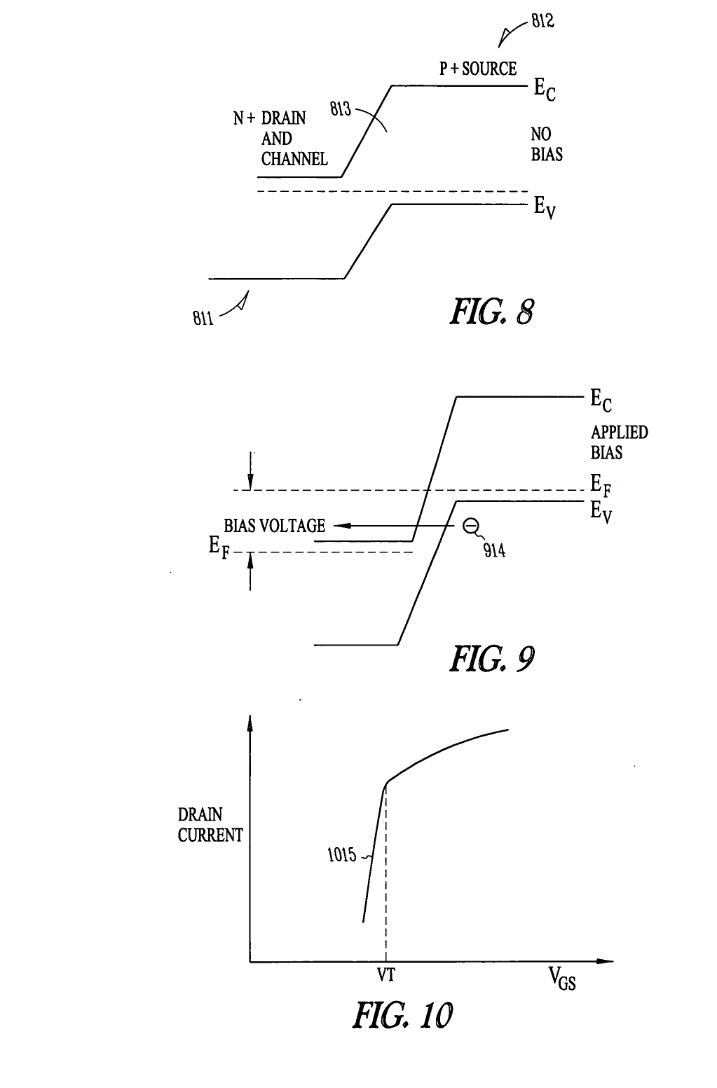

FIGS. 8 and 9 illustrate energy band diagrams of the operation of the transistor of FIG. 6. The upper line of each figure indicates the energy of the conduction band and the lower line indicates the energy of the valence band. FIG. 8 illustrates an energy band diagram of the electrical operation of the tunneling transistor of FIG. 7 when a transistor gate is not biased, according to various embodiments of the present subject matter. The diagram shows the channel and N+ second source/drain region 811 and P+ first source/drain region 812. In the non-conducting condition, a large barrier 813 exists between the source/drain regions. FIG. 9 illustrates an energy band diagram of the electrical operation of the tunneling transistor of FIG. 7 when a transistor gate is biased, according to various embodiments of the present subject matter. Electrical operation of the transistor is based on a MOS-gated pin-diode. Applying a bias to the gate creates a conducting condition in which an electron channel is induced to form once the electron concentration is degenerated. A tunnel junction 914 is formed at the P+ side of the channel. Applying a drain bias causes band bending and the N-type region conduction band to be below the valence band edge in the source region. Electrons can then tunnel from the source valence band to the induced n-type channel region resulting in drain current. Since there can be no tunneling until the conduction band edge in the channel is drawn below the valence band in the source, the turn-on characteristic is very sharp and the sub-threshold slope approaches the ideal value for a tunneling transistor of zero mV/decade as illustrated in FIG. 10.

FIG. 10 illustrates a plot of drain current versus the gate-to-source voltage of the tunneling transistor of the tunneling transistor of FIG. 7, and illustrates the sub-threshold leakage current, according to various embodiments of the present subject matter. This plot shows the very steep slope “S” for the sub-threshold current 1015 that results from the biasing of the embodiments of the tunneling transistor. The vertical, drain current axis of FIG. 10 is a log scale while the horizontal, VGS axis is linear.

Methods to Form Vertical Sublithographic Channels

The following discussion refers to silicon transistor embodiments. Those of ordinary skill in the art will understand, upon reading and comprehending this disclosure, how to use the teaching contained herein to form tunneling transistors with sublithographic channels using other semiconductors.

Method to Grow Nanowire Bodies

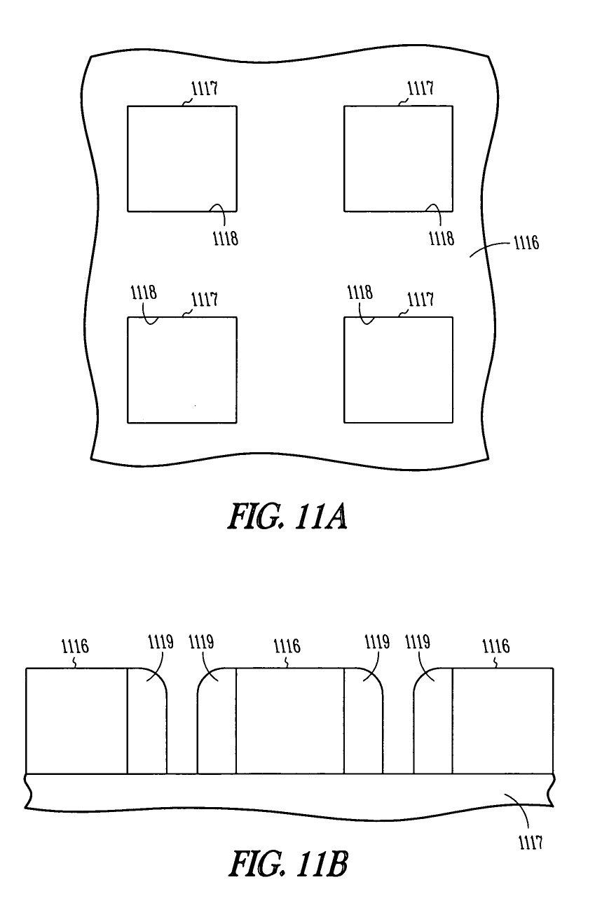

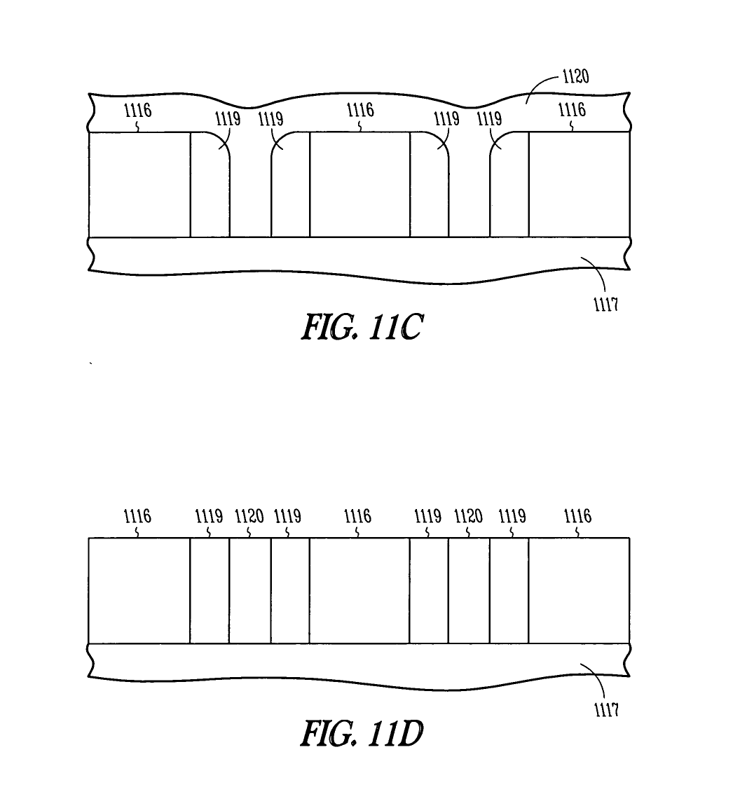

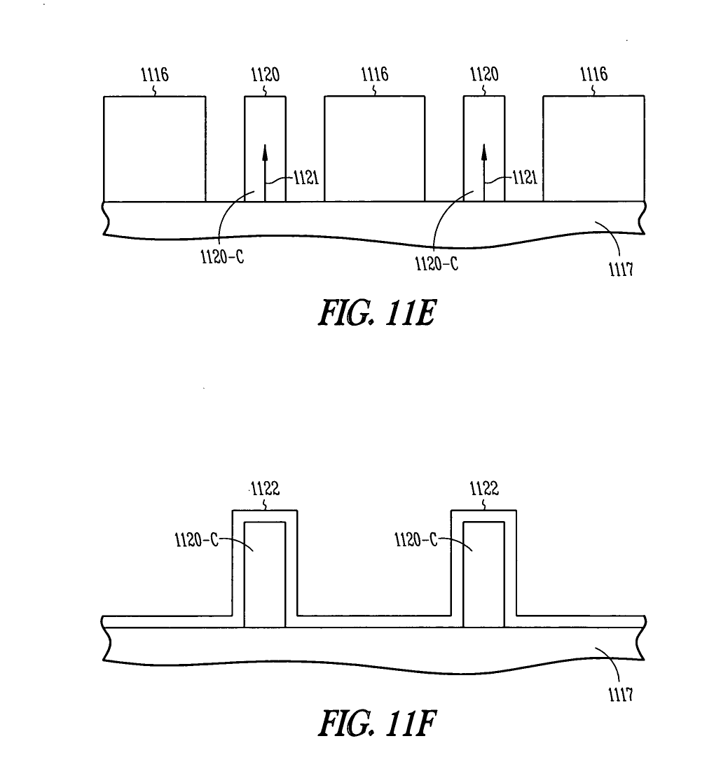

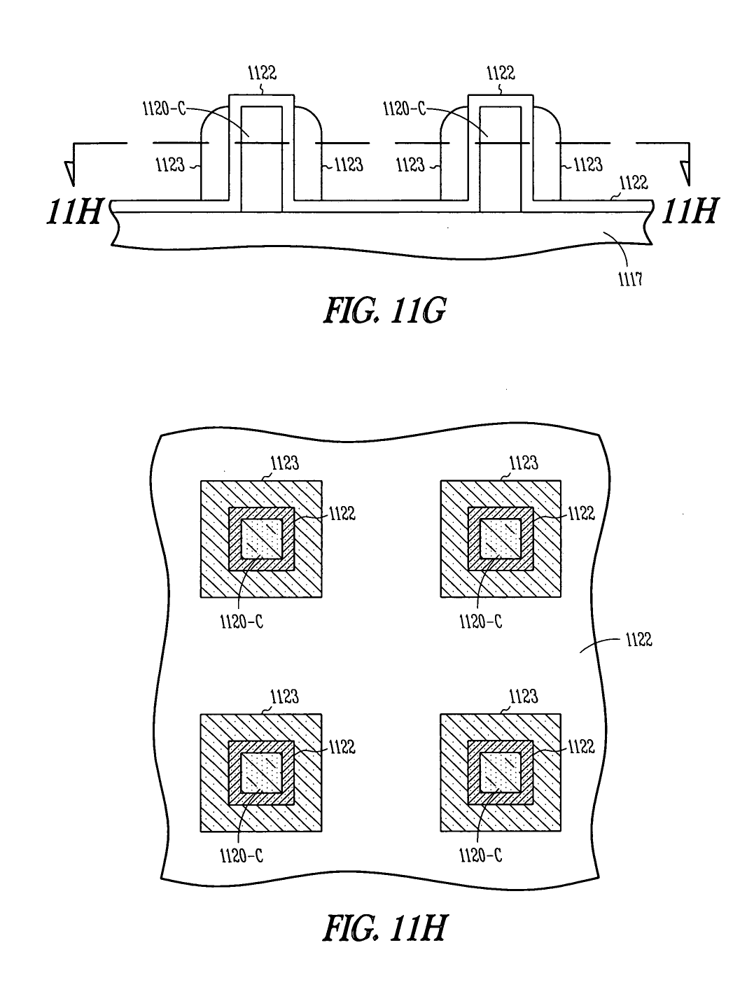

FIGS. 11A-11H illustrate a process for growing a nanowire body to provide a vertical channel for a tunneling transistor, according to various embodiments of present subject matter. The illustrated process forms crystalline nanorods with surrounding gates. The illustrated process is disclosed in U.S. application Ser. No. ______, entitled “Nanowire Transistor With Surrounding Gate,” (Attorney Docket No. 1303.167US1), which has been incorporated by reference in its entirety.

FIG. 11A illustrates a first layer 1116 on a substrate 1117, with holes 1118 formed in the first layer. The first layer is able to be etched to define the holes within the layer. According to various embodiments, the holes 1118 are formed in a silicon nitride layer 1116 on a silicon substrate 1117, such that the holes extend through the silicon nitride layer to the silicon substrate. In the illustrated embodiment, the holes are formed with dimensions corresponding to the minimum feature size. The center of each hole corresponds to the desired location of the nanowire transistor. An array of nanowire transistors can have a center-to-center spacing between rows and columns of 2F.

A layer of oxide is provided to cover the first layer after the holes have been etched therein. Various embodiments form a silicon oxide over the silicon nitride layer. Some embodiments deposit the silicon oxide by a chemical vapor deposition (CVD) process.

FIG. 11B illustrates the structure after the oxide is directionally etched to leave oxide sidewalls 1119 on the sides of the hole, which function to reduce the dimensions of the resulting hole, and the resulting structure is planarized. In 100 nm technology, for example, the oxide sidewalls reduce the dimensions of the hole to about 30 nm. In this example, the thickness of the body region for the transistor will be on the order of ⅓ of the feature size. Some embodiments planarize the structure using a chemical mechanical polishing (CMP) process.

FIG. 11C illustrates a thick layer of an amorphous semiconductor material 1120 formed over the resulting structure. The amorphous material fills the hole defined by the sidewalls 1119. Various embodiments deposit amorphous silicon as the amorphous material. FIG. 11D illustrates the resulting structure after it is planarized, such as by CMP, to leave amorphous semiconductor material only in the holes.

FIG. 11E illustrates the resulting structure after the sidewalls (e.g. silicon oxide sidewalls) are removed. The structure is heat treated to crystallize the amorphous semiconductor 1120 (e.g. a-silicon) into crystalline nanorods (represented as 1120-C) using a process known as solid phase epitaxy (SPE). The amorphous semiconductor pillar 1120 is in contact with the semiconductor wafer (e.g. silicon wafer), and crystal growth in the amorphous semiconductor pillar is seeded by the crystals in the wafer. The crystal formation from the SPE process is illustrated by the arrows 1121 in FIG. 11E.

FIG. 11F illustrates the structure after the first layer (e.g. silicon nitride) is removed, leaving crystalline nanorods 1120-C extending away from the substrate surface, and after a gate insulator 1122 is formed over the resulting structure. An embodiment forms the gate insulator by a thermal oxidation process. Thus, for an embodiment in which the wafer is a silicon wafer and the nanorods are crystalline silicon nanorods, the gate insulator is a silicon oxide. Other gate insulators, such as high K insulators, may be used.

FIG. 11G illustrates a side view and FIG. 11H illustrates a cross-section view along 11H-11H of FIG. 11G view of the structure after a gate material 1123 is formed on the sidewalls of the crystalline nanorods 1120-C. An embodiment deposits the gate material and etches the resulting structure to leave the gate material only on the sidewalls of the nanorods. Polysilicon is used as the gate material, according to various embodiments. The height of the pillars, which determines the channel length of the transistors, can be less than the minimum lithographic dimensions. Various embodiments provide a channel length on the order of approximately 100 nm. These nanorods with wraparound gates can be used to form nanowire transistors with surrounding or wraparound gates. Standalone transistors or arrays of transistors can be formed, as disclosed in U.S. application Ser. No. ______, entitled “Nanowire Transistor With Surrounding Gate,” (Attorney Docket No. 1303.167US1).

Method to Grow Nanofin Bodies

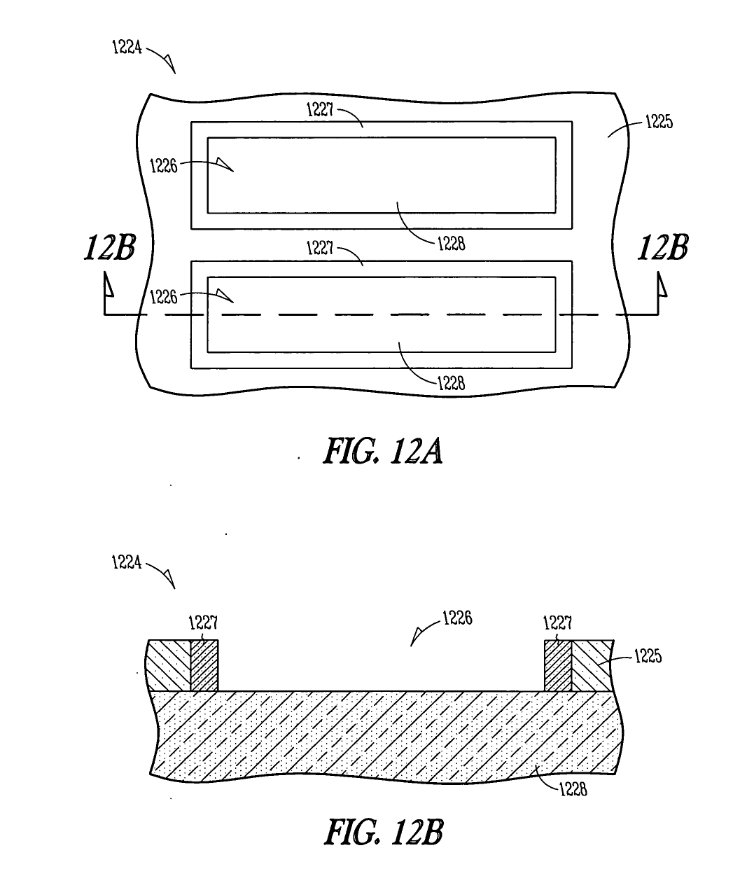

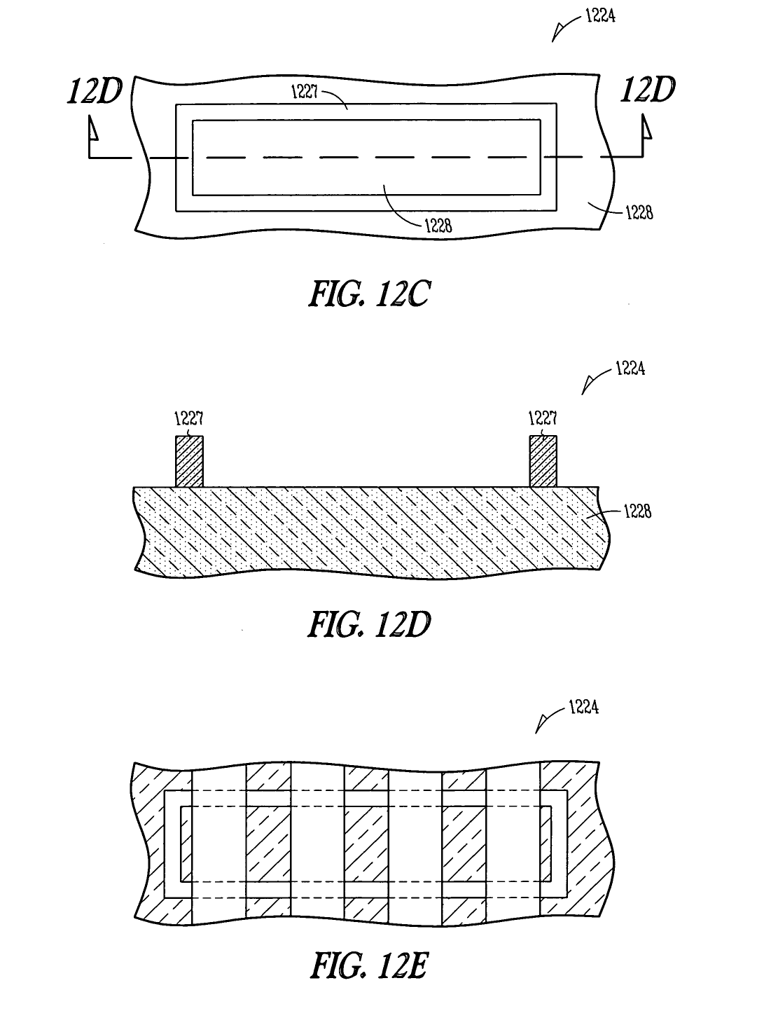

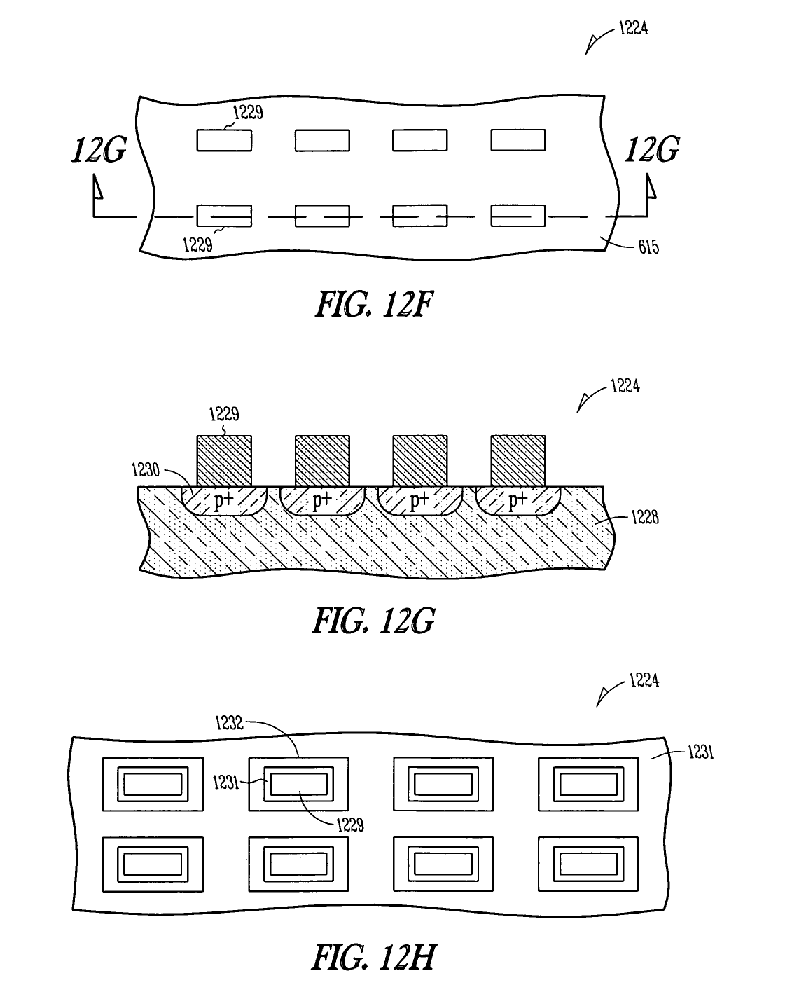

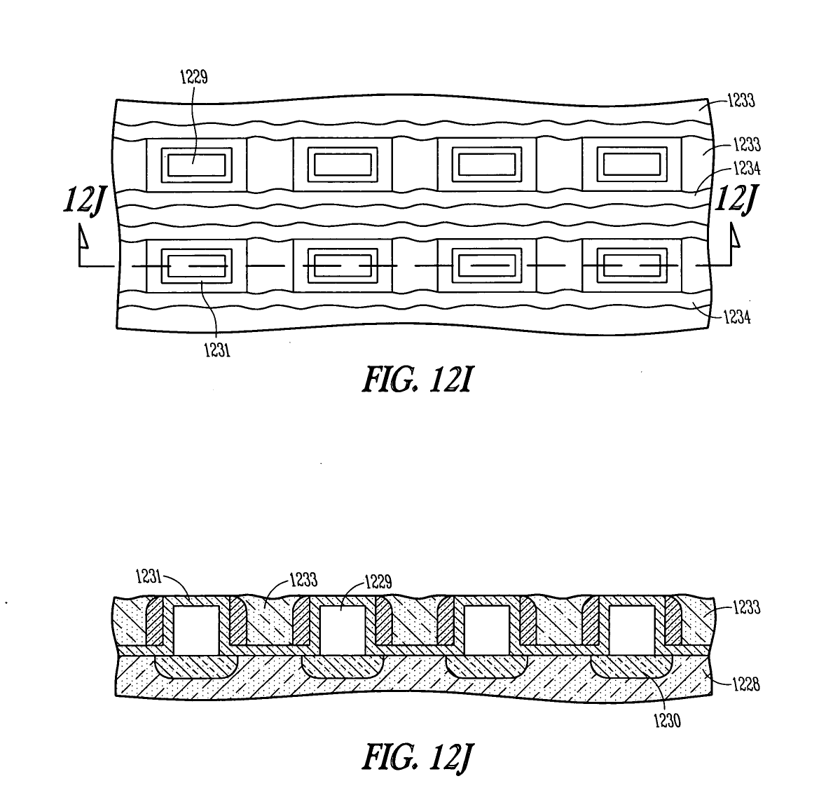

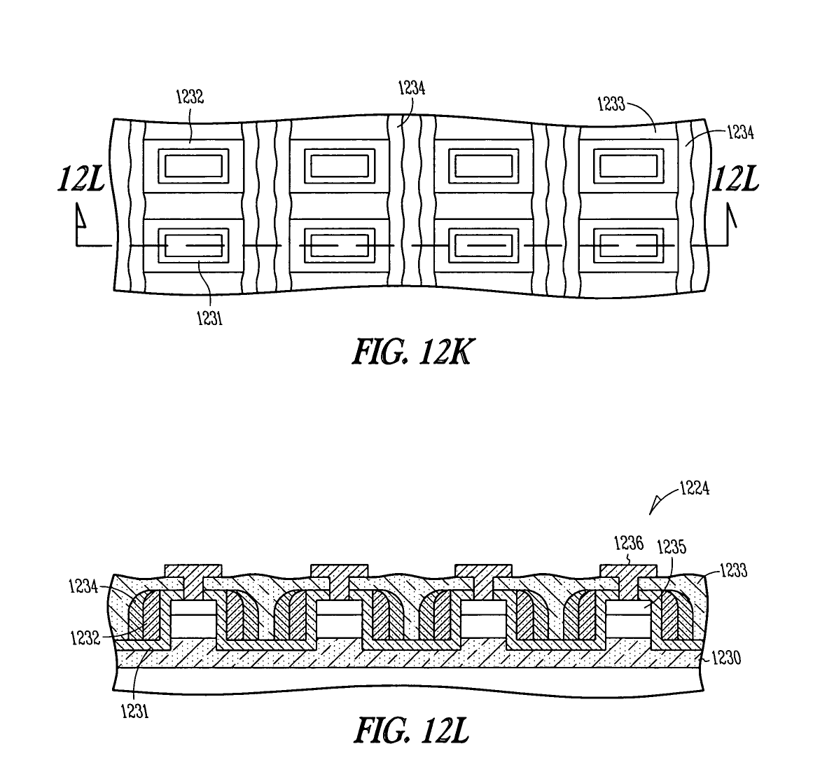

FIGS. 12A-12L illustrate a process for growing a nanofin body to provide a vertical channel for a tunneling transistor, according to various embodiments of present subject matter. The illustrated process is disclosed in U.S. application Ser. No. ______, entitled “Grown Nanofin Transistors,” (Attorney Docket No. 1303.168US1), which has been incorporated by reference in its entirety.

Disclosed herein are nanofin transistors, and a fabrication technique in which vertical amorphous silicon nanofins are recrystallized on a substrate to make single crystalline silicon nanofin transistors. Aspects of the present subject matter provide nanofin transistors with vertical channels, where there is a first source/drain region at the bottom of the fin and a second source/drain region at the top of the fin.

FIGS. 12A and 12B illustrate a top view and a cross-section view along 12B-12B, respectively, of a semiconductor structure 1224 with a silicon nitride layer 1225, holes 1226 in the silicon nitride layer, and sidewall spacers 1227 of amorphous silicon along the walls of the holes. The holes are etched in the silicon nitride layer, and amorphous silicon deposited and directionally etched to leave only on the sidewalls. The holes 1226 are etched through the silicon nitride layer 1225 to a silicon wafer or substrate 1228.

FIGS. 12C and 12D illustrate a top view and a cross-section view along line 12D-12D, respectively, of the structure 1224 after the silicon nitride layer is removed. As illustrated, after the silicon nitride layer is removed, the sidewalls 1227 are left as standing narrow regions of amorphous silicon. The resulting patterns of standing silicon can be referred to as “racetrack” patterns, as they have a generally elongated rectangular shape. The width of the lines is determined by the thickness of the amorphous silicon rather than masking and lithography. For example, the thickness of the amorphous silicon may be on the order of 20 nm to 50 nm, according to various embodiments. A solid phase epitaxial (SPE) growth process is used to recrystallize the standing narrow regions of amorphous silicon. The SPE growth process includes annealing, or heat treating, the structure to cause the amorphous silicon to crystallize, beginning at the interface with the silicon substrate 1228 which functions as a seed for crystalline growth up through the remaining portions of the standing narrow regions of silicon.

FIG. 12E illustrates a top view of the structure 1224, after a mask layer has been applied. The shaded areas are etched, leaving free-standing fins formed of crystalline silicon. FIGS. 12F and 12G illustrate a top view and a cross-section view along line 12G-12G, respectively, of the pattern of free-standing fins 1229. A buried doped region 1230 functions as a first source/drain region. According to various embodiments, the buried doped region can be patterned to form a conductive line either the row or column direction of the array of fins.

FIG. 12H illustrates a top view of the structure, where the fins have been surrounded by a gate insulator 1231 and a gate 1232. The gate insulator can be deposited or otherwise formed in various ways. For example, a silicon oxide can be formed on the silicon fin by a thermal oxidation process. The gate can be any gate material, such as polysilicon or metal. The gate material is deposited and directionally etched to leave the gate material only on the sidewalls of the fin structure with the gate insulator. The wiring can be oriented in either the “x-direction” or “y-direction”.

FIGS. 12I and 12J illustrate a top view and a cross-section view along line 12J-12J, respectively, of the structure illustrated in FIG. 12H after the structure is backfilled with an insulator 1233 and gate wiring 1234 is formed in an “x-direction” along the long sides of the fins. Various embodiments backfill the structure with silicon oxide. Trenches are formed in the backfilled insulator to pass along a side of the fins, and gate lines are formed in the trenches. In various embodiments, one gate line passes along one side of the fins, in contact with the surrounding gate of the fin structure. Some embodiments provide a first gate line on a first side of the fin and a second gate line on a second side of the fin. The gate wiring material, such as polysilicon or metal, can be deposited and directionally etched to leave on the sidewalls only. The gate wiring material appropriately contacts the surrounding gates for the fins. In various embodiments, the gate material and gate wiring material are etched to recess the gate and gate wiring below the tops of the fins. The whole structure can be backfilled with an insulator, such as silicon oxide, and planarized to leave only oxide on the surface. The top of the pillars or fins can be exposed by an etch. A second source/drain region can be implanted in a top portion of the fins, and metal contacts to the drain regions can be made by conventional techniques. The metal wiring can run, for example, in the “x-direction” and the buried source wiring can run perpendicular, in the plane of the paper in the illustration.

FIGS. 12K and 12L illustrate a top view and a cross-section view along line 12L-12L, respectively, of the structure after the structure is backfilled with an insulator and gate wiring is formed in an “y-direction” along the short sides of the fins. Trenches are opened up along the side of the fins in the “y-direction”. Gate wiring material 1234, such as polysilicon or metal, can be deposited and directionally etched to leave on the sidewalls only and contacting the gates on the fins. In various embodiments, the gate material and gate wiring material are etched to recess the gate and gate wiring below the tops of the fins. The whole structure can be backfilled with an insulator 1233, such as silicon oxide, and planarized to leave only the backfill insulator on the surface. Contact openings and drain doping regions can then be etched to the top of the pillars and drain regions implanted 1235 and metal contacts 1236 to the drain regions made by conventional techniques. The metal wiring can run, for example, perpendicular to the plane of the paper in the illustration and the buried source wiring 1230 runs in the “x-direction”. The buried source/drains are patterned and implanted before deposition of the amorphous silicon. FIG. 12L gives an illustration of one of the completed fin structures with drain/source regions, recessed gates, and source/drain region wiring. These nanofin FETs can have a large W/L ratio and are able to conduct more current than nanowire FETs.

Method to Etch Nanofin Bodies

Disclosed herein are nanofin transistors, and a fabrication technique in which nanofins are etched into a substrate or wafer and used to make single crystalline nanofin transistors. The following discussion refers to a silicon nanofin embodiment. Those of ordinary skill in the art will understand, upon reading and comprehending this disclosure, how to form nanofins using other semiconductors.

Aspects of the present subject matter provide nanofin transistors with vertical channels, where there is a first source/drain region at the bottom of the fin and a second source/drain region at the top of the fin.

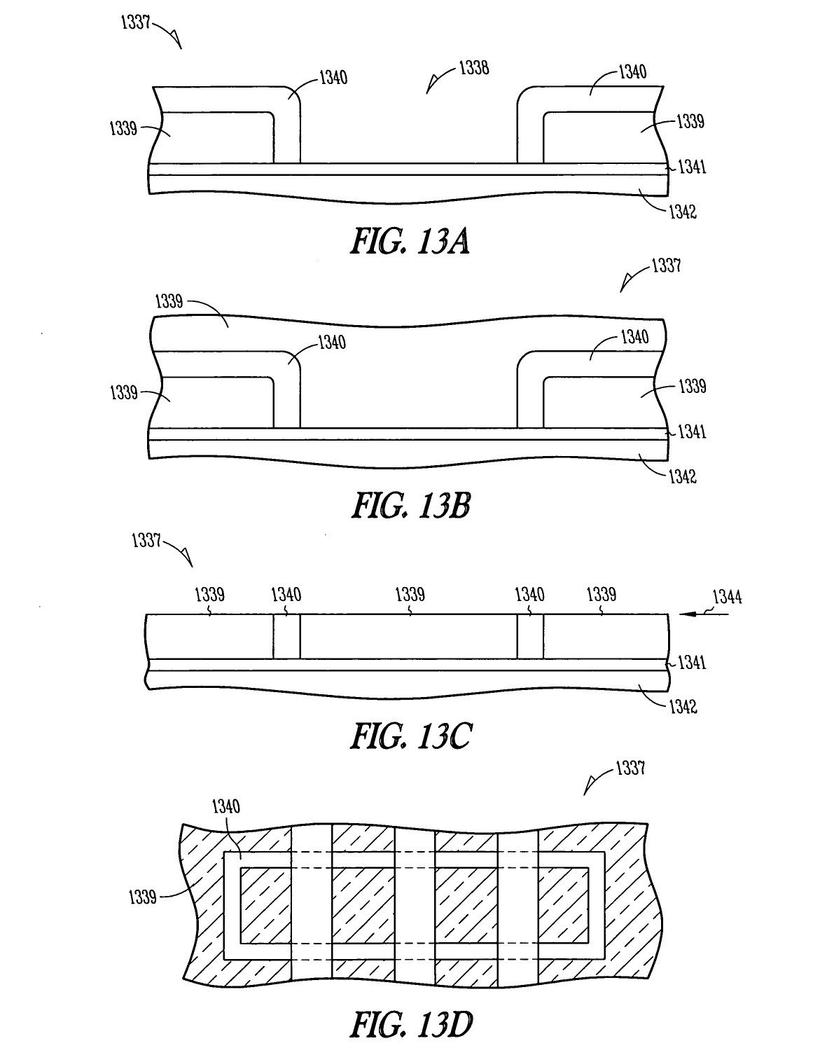

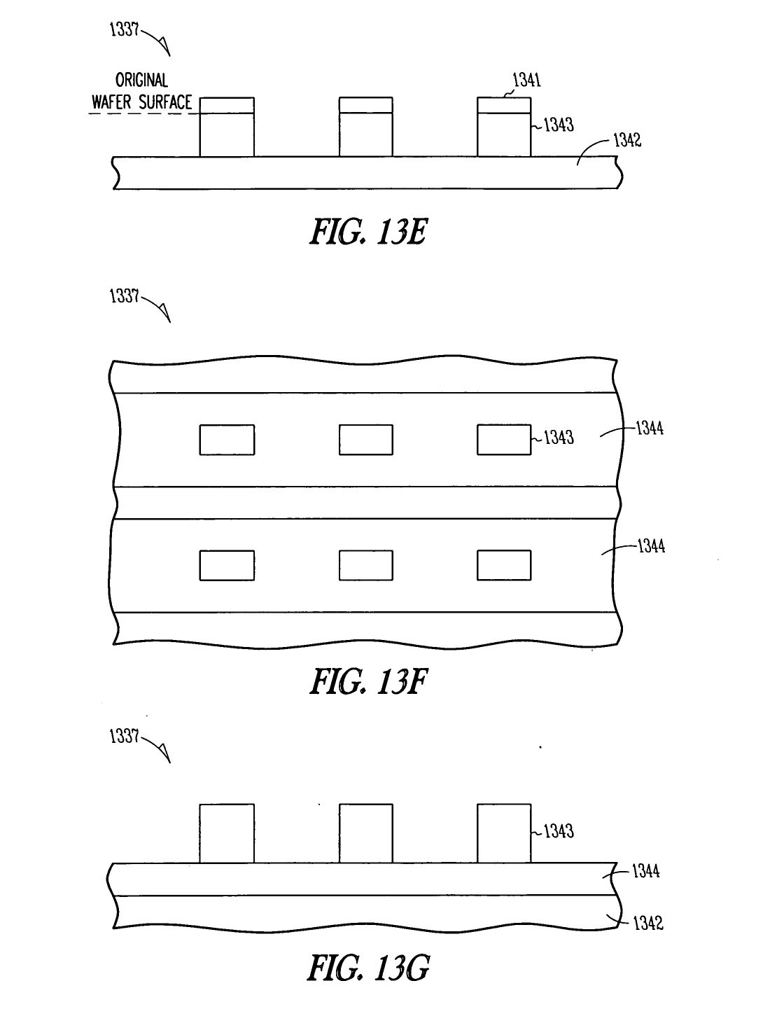

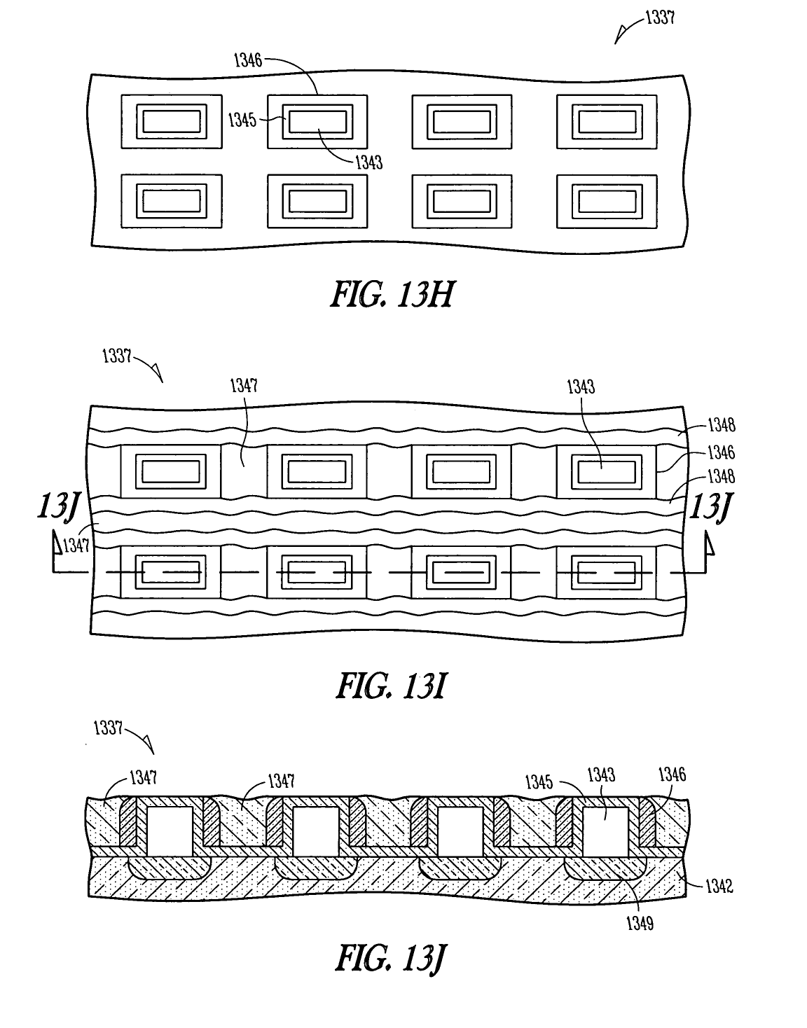

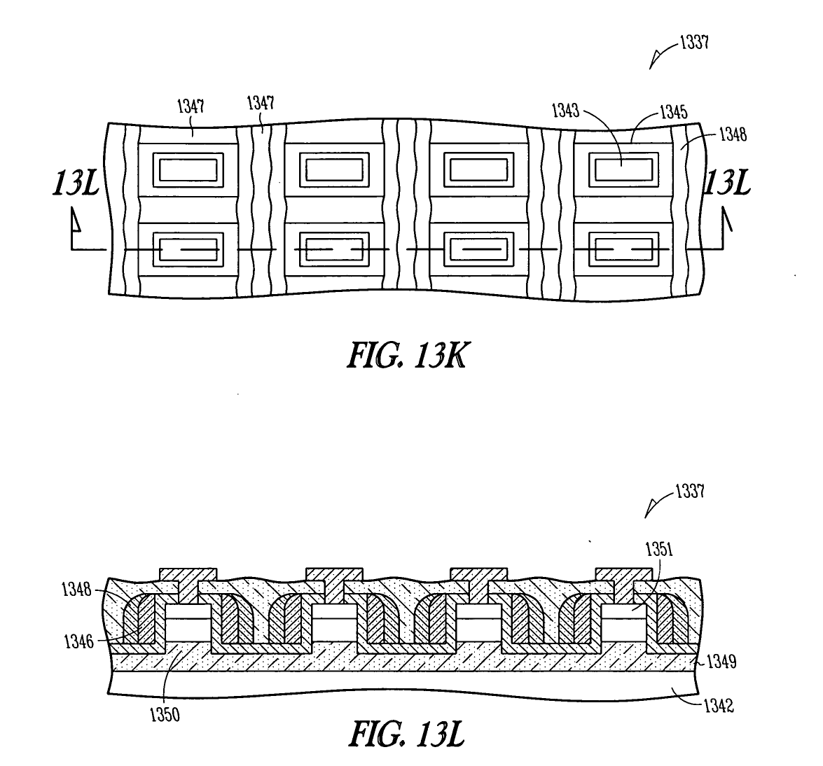

According to an embodiment, silicon nitride is deposited on a silicon wafer, and the silicon nitride is covered with a layer of amorphous silicon (a-silicon). FIG. 13A illustrates a side view of the structure 1337 after holes 1338 are defined in the amorphous silicon 1339 and sidewall spacers 1340 are formed. The holes 1338 extend to the silicon nitride layer 1341, which lies over a substrate 1342 such as a silicon wafer. Various embodiments form the sidewall spacers by oxidizing the amorphous silicon. FIG. 13B illustrates a side view of the structure 1337, after the structure is covered with a thick layer of amorphous silicon 1339. FIG. 13C illustrates the structure 1337 after the structure is planarized, illustrated by arrow 1344, at least to a level to remove the oxide on top of the amorphous silicon. The structure can be planarized using a chemical mechanical polishing (CMP) process, for example. This leaves an elongated rectangular pattern, also referred to as a “racetrack” pattern, of oxide 1340 exposed on the surface. The width of the pattern lines is determined by the oxide thickness rather than masking and lithography. For example, the oxide thickness can be within a range on the order of 20 nm to 50 nm, according to various embodiments.

FIG. 13D illustrates a mask over the racetrack pattern, which selectively covers portions of the oxide and exposes other portions of the oxide. The exposed oxide portions, illustrated by the shaded strips, are removed. An etch process, such as a potassium hydroxide (KOH) etch, is performed to remove the amorphous silicon. The oxide, or the portions of the oxide remaining after the mask and etch illustrated in FIG. 13D, protects the nitride during the etch. After the amorphous silicon is removed the nitride 1341 can be etched, followed by a directional silicon etch that etches the wafer 1342 to a predetermined depth below the nitride layer. The nitride pattern protects the local areas of silicon from the etch, resulting in silicon fins 1343 of silicon protruding from the now lower surface of the silicon wafer, as illustrated in FIG. 13E. FIGS. 13F and 13G illustrate top and side views of the structure, after the tops of the fins and trenches at the bottom of the fins are implanted with a dopant. As illustrated in FIG. 13F, the dopant in the trench forms a conductive line 1344 (e.g. source line). The dopant also forms a source/drain region at the bottom or a bottom portion of the fin. Because the fins are extremely thin, the doping in the trench is able to diffuse completely under the fins. The strips can be in either the row or column direction.

FIG. 13H illustrates the structure 1337 after a gate insulator 1345 has been formed around the fin 1343, and a gate material 1346 is formed around and separated from the fin by the gate insulator. For example, an embodiment oxidizes the silicon fins using a thermal oxidation process. The gate material 1346 may be polysilicon or metal, according to various embodiments.

FIGS. 13I and 13J illustrate a top view and a cross-section view along line 13J-13J, respectively, of a first array embodiment. The structure 1337 is backfilled with an insulator 1347 (e.g. oxide) and trenches are created on the sides of the fins. Gate wiring material 1348, such as polysilicon or metal, can be deposited and directionally etched to leave on the sidewalls only and contacting the surrounding gates 1346 for the fins. The gate material and gate wiring material can be etched to recess it below the tops of the fins. The whole structure can be again backfilled with oxide and planarized to leave only oxide on the surface. Contact openings and drain doping regions can then be etched to the top of the pillars and drain regions implanted and metal contacts to the drain regions made by conventional techniques. In this case the metal wiring could run in the “x-direction” and the buried source wiring 1349 could run perpendicular to the plane of the paper in the illustration.

FIGS. 13K and 13L illustrate a top view and a cross-section view along 13L-13L, respectively, of a second array embodiment. The structure 1337 is backfilled with an insulator 1347 (e.g. oxide) and trenches are created along the side of the fins 1343, in the “y-direction”. Gate wiring material 1348, such as polysilicon or metal, can be deposited and directionally etched to leave on the sidewalls only and contacting the gates on the fins. The gate material and gate wiring material can be etched to recess it below the tops of the fins. The whole structure can be backfilled with an insulator (e.g. oxide) and planarized to leave only oxide on the surface. Contact openings and drain doping regions can then be etched to the top of the pillars and drain regions implanted and metal contacts to the drain regions made by conventional techniques. In this case the metal wiring could run perpendicular to the plane of the paper in the illustration and the buried source wiring could run in the “x-direction”.

In both the first and second array embodiments, the buried source/drains can be implanted before the formation of the surrounding gate insulator and surrounding gate. FIG. 13L illustrates one of the completed fin structures with drain/source regions 1350 and 1351, recessed gates 1346, and source/drain region wiring 1349. These nanofin FETs can have a large W/L ratio and will conduct more current than nanowire FETs.

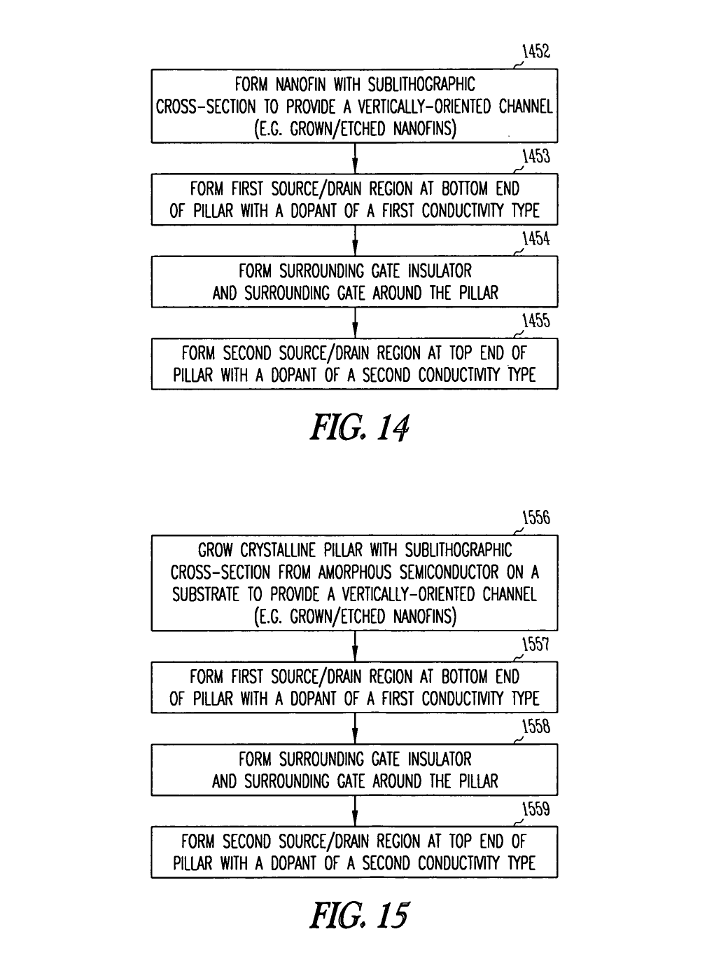

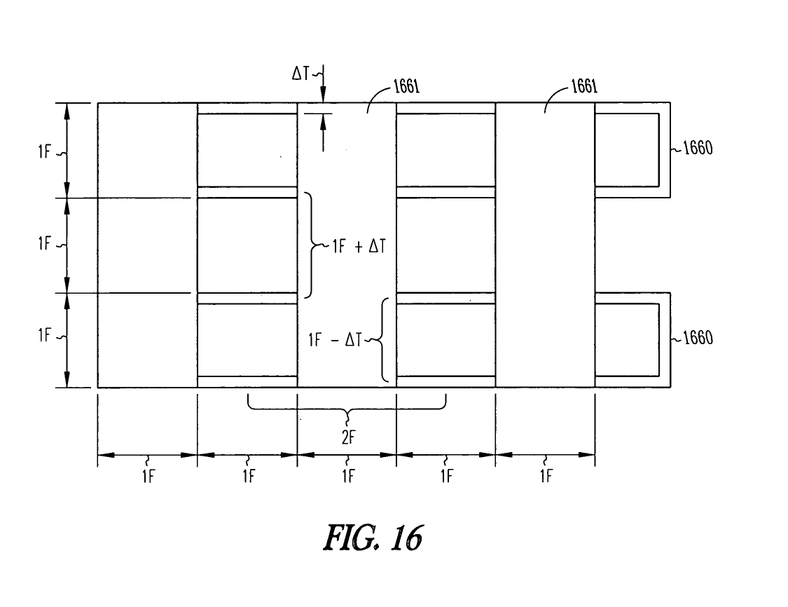

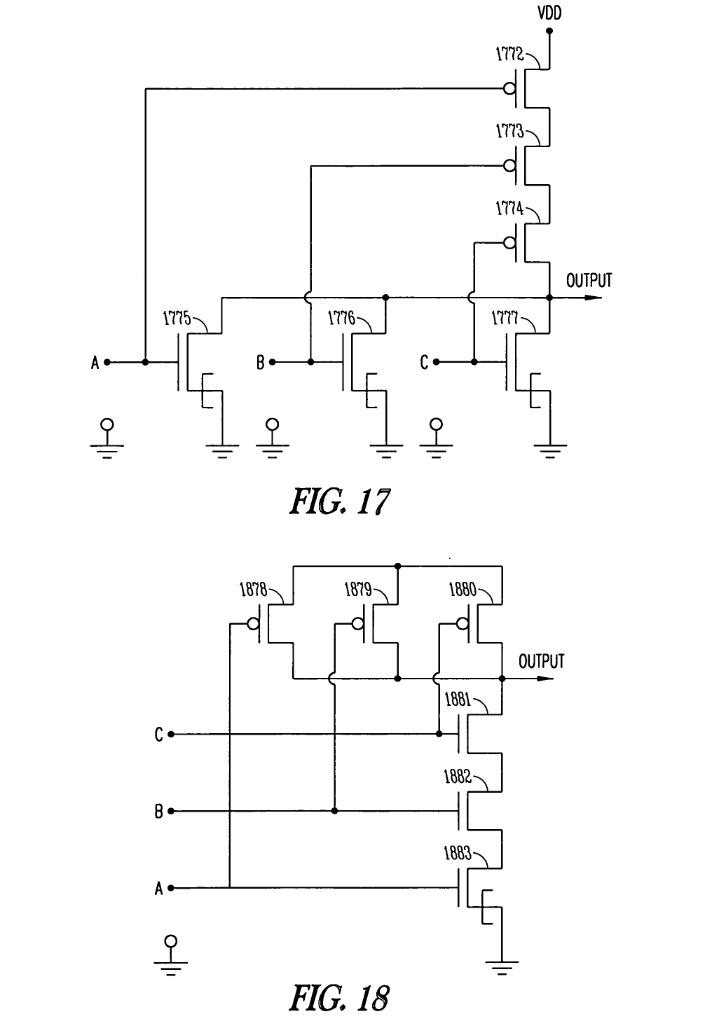

The processes illustrated in FIGS. 11A-11H, 12A-12L, and 13A-13L can also be generally illustrated using flow diagrams, such as provided by FIGS. 14 and 15. FIG. 14 illustrates a method to form a tunneling nanofin transistor, according to various embodiments of the present subject matter. In the illustrated embodiment, a nanofin is formed with a sublithographic cross-section at 1452. A vertically-oriented channel will be defined in the nanofin. The nanofin can be formed by growing a crystalline nanofin such as is illustrated in FIGS. 12A-12L, and can be formed by etching a crystalline substrate to define the nanofin such as is illustrated in FIGS. 13A-13L. At 1453, a first source/drain region is formed at a bottom end of the pillar. The first source/drain region is of a first conductivity type, such as a P+ region. The first source/drain region can be formed before the nanofin is formed. The first source/drain region can also be formed after the nanofin is formed, since the nanofin is very thin and an implanted dopant is able to diffuse completely underneath the nanofin. At 1454, a surrounding gate insulator is formed around the nanofin and a surrounding gate is formed around and separated from the nanofin by the surrounding gate insulator. At 1455, a second source/drain region is formed at a top end of the nanofin. The second source/drain region is of a second conductivity type (e.g. N+) different than the first conductivity type. It is noted that the first source/drain region can be of the second conductivity type (N+) and the second source/drain region can be of the first conductivity type (P+).

FIG. 15 illustrates a method to grow a sublithographic transistor body for a tunneling transistor, according to various embodiments of the present subject matter. At 1556, a crystalline pillar is grown with a sublithographic cross-section from amorphous semiconductor on a substrate. A vertically-oriented channel will be defined in the crystalline pillar. The pillar can be a nanowire such as illustrated at FIGS. 11A-11H, or a nanofin such as illustrated at FIGS. 12A-12L. At 1557, a first source/drain region is formed at a bottom end of the pillar. The first source/drain region is of a first conductivity type, such as a P+ region. The first source/drain region can be formed before the crystalline pillar is formed. The first source/drain region can also be formed after the crystalline pillar is formed, since the pillar is very thin and an implanted dopant is able to diffuse completely underneath the pillar. At 1558, a surrounding gate insulator is formed around the pillar and a surrounding gate is formed around and separated from the pillar by the surrounding gate insulator. At 1559, a second source/drain region is formed at a top end of the pillar. The second source/drain region is of a second conductivity type (e.g. N+) different than the first conductivity type. It is noted that the first source/drain region can be of the second conductivity type (N+) and the second source/drain region can be of the first conductivity type (P+). Standalone transistors or arrays of transistors can be formed.

Nanofin Array

FIG. 16 illustrates a top view of a layout of nanofins for an array of nanofin transistors, according to various embodiments. The figure illustrates two “racetracks” of sidewall spacers 1660, and further illustrates the portions of the sidewall spacers removed by an etch. The holes used to form the sidewall spacer tracks were formed with a minimum feature size (1F). The mask strips 1661 have a width of a minimum feature size (1F) and are separated by a minimum feature size (1F). In the illustrated layout, the columns of the nanofins have an approximately 2F center-to-center spacing, and the rows of the nanofins have an approximately 1F center-to-center spacing. Also, as illustrated in FIG. 16, since the nanofins are formed from sidewall spacers on the walls of the holes, the center-to-center spacing between first and second rows will be slightly less than 1F size by an amount corresponding to the thickness of the nanofins (1F−ΔT), and the center-to-enter spacing between second and third rows will be slightly more than 1F by an amount corresponding to the thickness of the nanofins (1F+ΔT). In general, the center-to-center spacing between first and second rows will be slightly less than a feature size interval (NF) by an amount corresponding to the thickness of the nanofins (NF−ΔT), and the center-to-center spacing between second and third rows will be slightly more than a feature size interval (NF) by an amount corresponding to the thickness of the nanofins (NF+ΔT).

Logic Circuits

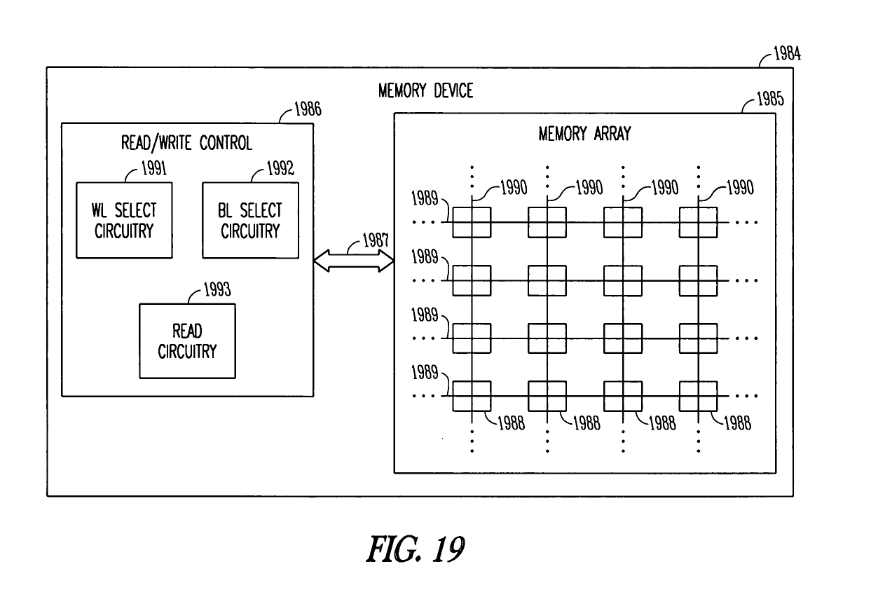

FIG. 17 illustrates a NOR gate logic circuit that includes tunneling transistors, according to various embodiments of the present subject matter. The A, B, and C inputs introduce the logic levels for the illustrated CMOS logic circuit. A logic low input signal on any of these inputs turns on its respective PMOS transistor 1772-1774 and turns off its respective tunneling transistor 1775-1777. A logic high input signal has the opposite effect. Turning on any of the tunneling transistors 1775-1777 has the effect of bringing the output to ground (i.e., a logic 0). Turning on all of the PMOS transistors 1772-1774 has the effect of taking the output to VDD (i.e., a logic 1).

FIG. 18 illustrates a NAND gate logic circuit that includes a tunneling transistor, according to various embodiments of the present subject matter. This application incorporates the tunneling transistor into a NAND gate CMOS logic circuit as the NMOS transistor closest to Vss. A logic low input signal on any of the three inputs A, B, C causes its respective PMOS device 1878-1880 to turn on and pull the output to a logic high. A logic high on all of the inputs turns on the respective NMOS transistors 1881-1882 and tunneling transistor 1883 that pulls the output to a logic low.

The tunneling transistors of the present subject matter provide substantially reduced sub-threshold leakage current and, thus, reduced power operation of CMOS circuits, such as has been illustrated by the NOR gate and NAND gate logic circuits of FIGS. 17 and 18, respectively. These embodiments are for purposes of illustration only since the tunneling transistor of the present subject matter can be used in any transistor circuit.

Higher Level Device/Systems

FIG. 19 is a simplified block diagram of a high-level organization of various embodiments of a memory device according to various embodiments of the present subject matter. The illustrated memory device 1984 includes a memory array 1985 and read/write control circuitry 1986 to perform operations on the memory array via communication line(s) or channel(s) 1987. The illustrated memory device 1954 may be a memory card or a memory module such as a single inline memory module (SIMM) and dual inline memory module (DIMM). One of ordinary skill in the art will understand, upon reading and comprehending this disclosure, that semiconductor components in the memory array and/or the control circuitry are able to be fabricated using the tunneling transistors, as described above. The structure and fabrication methods for these devices have been described above. The memory array 1985 includes a number of memory cells 1988. The memory cells in the array are arranged in rows and columns. In various embodiments, word lines 1989 connect the memory cells in the rows, and bit lines 1990 connect the memory cells in the columns. The read/write control circuitry 1986 includes word line select circuitry 1991 which functions to select a desired row, bit line select circuitry 1992 which functions to select a desired column, and read circuitry 1993 which functions to detect a memory state for a selected memory cell in the memory array 1985.

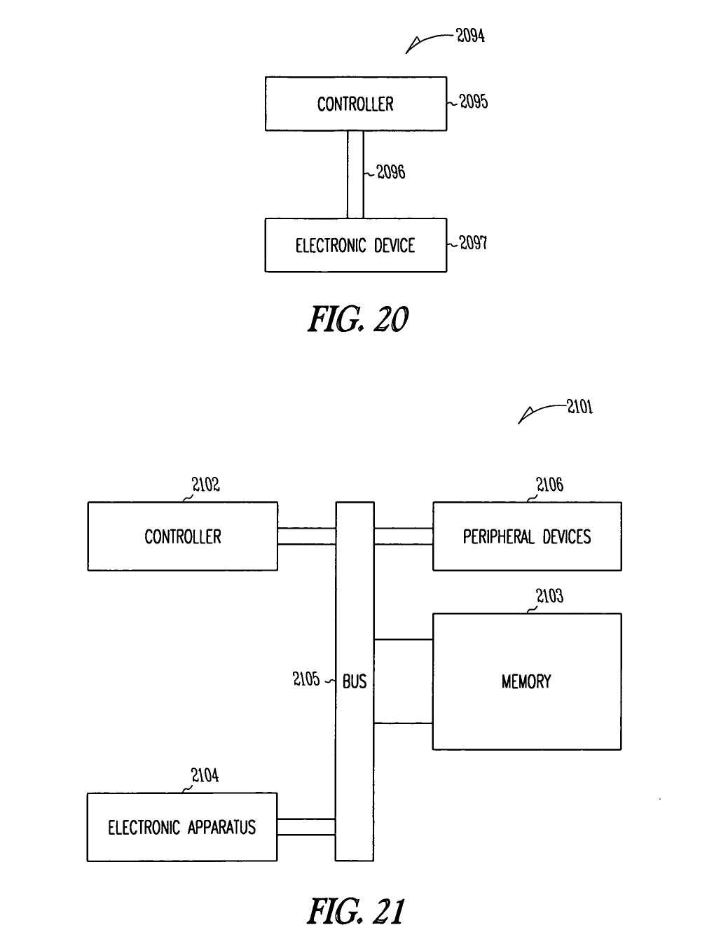

FIG. 20 illustrates a diagram for an electronic system having one or more tunneling transistors, according to various embodiments. Electronic system 2094 includes a controller 2095, a bus 2096, and an electronic device 2097, where the bus 2096 provides communication channels between the controller 2095 and the electronic device 2097. In various embodiments, the controller and/or electronic device include tunneling transistors as previously discussed herein. The illustrated electronic system 2094 may include, but is not limited to, information handling devices, wireless systems, telecommunication systems, fiber optic systems, electro-optic systems, and computers.

FIG. 21 depicts a diagram of an embodiment of a system 2101 having a controller 2102 and a memory 2103. The controller 2102 and/or memory 2103 may include tunneling transistors according to various embodiments. The illustrated system 2101 also includes an electronic apparatus 2104 and a bus 2105 to provide communication channel(s) between the controller and the electronic apparatus, and between the controller and the memory. The bus may include an address, a data bus, and a control bus, each independently configured; or may use common communication channels to provide address, data, and/or control, the use of which is regulated by the controller. In an embodiment, the electronic apparatus 2104 may be additional memory configured similar to memory 2103. An embodiment may include a peripheral device or devices 2106.coupled to the bus 2105. Peripheral devices may include displays, additional storage memory, or other control devices that may operate in conjunction with the controller and/or the memory. In an embodiment, the controller is a processor. Any of the controller 2102, the memory 2103, the electronic apparatus 2104, and the peripheral devices 2106 may include tunneling transistors formed according to various embodiments. The system 2101 may include, but is not limited to, information handling devices, telecommunication systems, and computers. Applications containing tunneling transistors, as described in this disclosure include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

The memory may be realized as a memory device containing tunneling transistors according to various embodiments. It will be understood that embodiments are equally applicable to any size and type of memory circuit and are not intended to be limited to a particular type of memory device. Memory types include a DRAM, SRAM (Static Random Access Memory) or Flash memories. Additionally, the DRAM could be a synchronous DRAM commonly referred to as SGRAM (Synchronous Graphics Random Access Memory), SDRAM (Synchronous Dynamic Random Access Memory), SDRAM II, and DDR SDRAM (Double Data Rate SDRAM). Various emerging memory technologies are capable of using transistors with tunneling transistors.

This disclosure includes several processes, circuit diagrams, and cell structures. The present subject matter is not limited to a particular process order or logical arrangement. Although specific embodiments have been illustrated and described herein, it will be appreciated by those of ordinary skill in the art that any arrangement which is calculated to achieve the same purpose may be substituted for the specific embodiments shown. This application is intended to cover adaptations or variations of the present subject matter. It is to be understood that the above description is intended to be illustrative, and not restrictive. Combinations of the above embodiments, and other embodiments, will be apparent to those of skill in the art upon reviewing the above description. The scope of the present subject matter should be determined with reference to the appended claims, along with the full scope of equivalents to which such claims are entitled.

What is claimed is:

1. A transistor, comprising:
a nanofin with a sublithographic cross-sectional width in a first direction and a cross-sectional width in a second direction orthogonal to the first direction that corresponds to a minimum feature size;
a surrounding gate insulator around the nanofin;
a surrounding gate around and separated from the nanofin by the surrounding gate insulator; and
a first source/drain region of a first conductivity type at a bottom end of the nanofin and a second source/drain region of a second conductivity type at a top end of the nanofin to define a vertically-oriented channel region between the first source/drain region and the second source/drain region.

2. The transistor of claim 1, wherein the nanofin is formed from a crystalline substrate, and trenches etched in the substrate define the nanofin.

3. The transistor of claim 1, wherein the nanofin is formed on a substrate surface.

4. The transistor of claim 1, wherein the first source/drain region has an P+ conductivity and the second source/drain region has an N+ conductivity.

5. The transistor of claim 4, further comprising a P+ conduction line in the substrate and connected to the first source/drain region.

6. A method for forming a transistor, comprising:
forming a nanofin with a sublithographic cross-sectional width in a first direction and a cross-sectional width in a second direction orthogonal to the first direction that corresponds to a minimum feature size;
forming a surrounding gate insulator around the nanofin; and
forming a surrounding gate around and separated from the nanofin by the surrounding gate insulator,
wherein the nanofin is adapted to provide a vertically oriented channel between a first source/drain region of a first conductivity type and a second source/drain region of a second conductivity type.

7. The method of claim 6, wherein forming a nanofin includes forming an amorphous semiconductor pillar on a substrate and recrystallizing the semiconductor pillar to form the nanofin.

8. The method of claim 6, wherein forming a nanofin includes etching trenches in a crystalline substrate to form the nanofin from the substrate.

9. The method of claim 6, wherein the first source/drain region has an P+ conductivity and the second source/drain region has an N+ conductivity.

10. The method of claim 9, further comprising forming a P+ conduction line in the substrate to contact the first source/drain region.

11. A transistor, comprising:
a crystalline pillar with at least one sublithographic cross-sectional dimension formed on a substrate surface;
a surrounding gate insulator around the crystalline pillar; and
a surrounding gate around and separated from the crystalline pillar by the surrounding gate insulator,
wherein the crystalline pillar is adapted to provide a vertically-oriented channel region between a first source/drain region of a first conductivity type and a second source/drain region of a second conductivity type.

12. The transistor of claim 11, wherein the first source/drain region has an P+ conductivity and the second source/drain region has an N+ conductivity.

13. The transistor of claim 12, further comprising a P+ conduction line in the substrate and connected to the first source/drain region.

14. The transistor of claim 11, wherein the crystalline pillar is a crystalline nanowire with a sublithographic cross-sectional width in a first direction and a sublithographic cross-sectional width in a second direction orthogonal to the first direction.

15. The transistor of claim 11, wherein the crystalline pillar is a crystalline nanofin with a sublithographic cross-sectional width in a first direction and a cross-sectional width in a second direction orthogonal to the first direction that corresponds to a minimum feature size.

16. A method for forming a transistor, comprising:
forming a crystalline pillar with at least one sublithographic cross-sectional dimension, including forming an amorphous semiconductor pillar on a substrate and recrystallizing the semiconductor pillar to form the crystalline pillar;
forming a surrounding gate insulator around the crystalline pillar; and
forming a surrounding gate around and separated from the crystalline pillar by the surrounding gate insulator,
wherein the crystalline pillar is adapted to provide a vertically-oriented channel region between a first source/drain region of a first conductivity type and a second source/drain region of a second conductivity type.

17. The method of claim 16, wherein forming a crystalline pillar with at least one sublithographic cross-sectional dimension includes forming a crystalline nanofin with a sublithographic cross-sectional width in a first direction and a cross-sectional width in a second direction orthogonal to the first direction that corresponds to a minimum feature size.

18. The method of claim 16, wherein forming a crystalline pillar with at least one sublithographic cross-section dimension includes forming crystalline nanowire with a sublithographic cross-sectional width in a first direction and a sublithographic cross-sectional width in a second direction orthogonal to the first direction.

19. The method of claim 16, wherein the first source/drain region has an P+ conductivity and the second source/drain region has an N+ conductivity.

20. The method of claim 19, further comprising a P+ conduction line formed in the substrate and connected to the first source/drain region.

21. A method for forming a transistor, comprising:
forming a transistor body, including:
forming a pillar of amorphous semiconductor material on a crystalline substrate, the pillar having a sublithographic thickness; and
performing a solid phase epitaxy (SPE) process to crystallize the amorphous semiconductor material using the crystalline substrate to seed the crystalline growth, the transistor body being formed in the crystallized semiconductor pillar between a first source/drain region of a first conductivity type and a second source/drain region of a second conductivity type;
forming a surrounding gate insulator around the semiconductor pillar; and
forming a surrounding gate around and separated from the semiconductor pillar by the surrounding gate insulator.

22. The method of claim 21, wherein forming a pillar of amorphous semiconductor material on a crystalline substrate includes forming a pillar of amorphous silicon on a crystalline silicon substrate.

23. The method of claim 21, wherein forming the surrounding gate insulator includes forming a silicon oxide.

24. The method of claim 21, wherein forming a surrounding gate includes forming a polysilicon gate.

25. The method of claim 21, wherein forming a surrounding gate includes forming a metal gate.

26. The method of claim 21, further comprising recessing the surrounding gate such that the surrounding gate has a height less than a height of the pillar.

27. The method of claim 21, further comprising forming the first source/drain region in the substrate and forming the second source/drain region in a top portion of the pillar.

28. A transistor, comprising:
a crystalline substrate;
a first source/drain region of a first conductivity type formed in the crystalline substrate;
a crystalline semiconductor pillar formed on the substrate in contact with the first source/drain region, the semiconductor pillar having cross-section dimensions less than a minimum feature size;
a second source/drain region of a second conductivity type formed in a top portion of the pillar;
a gate insulator formed around the pillar; and
a surrounding gate formed around and separated from the pillar by the gate insulator.

29. The transistor of claim 28, wherein the semiconductor pillar has a cross-section dimension on the order of one third of the minimum feature size.

30. The transistor of claim 28, wherein the semiconductor pillar has a cross-section dimension on the order of 30 nm.

31. The transistor of claim 28, wherein the gate insulator includes silicon oxide.

32. The transistor of claim 28, wherein the gate includes a polysilicon gate.

33. The transistor of claim 28, wherein the gate includes a metal gate.

34. A method for forming a transistor, comprising:
forming a transistor body, including:
forming a fin of amorphous semiconductor material on a crystalline substrate, the fin having a cross-sectional thickness in at least one direction less than a minimum feature size; and
performing a solid phase epitaxy (SPE) process to crystallize the amorphous semiconductor material using the crystalline substrate to seed the crystalline growth, the transistor body being formed in the crystallized semiconductor pillar between a first source/drain region of a first conductivity type and a second source/drain region of a second conductivity type;
forming a surrounding gate insulator around the semiconductor pillar; and
forming a surrounding gate around and separated from the semiconductor pillar by the surrounding gate insulator.

35. The method of claim 34, wherein the fin has a cross-sectional thickness in a first direction corresponding to a minimum feature length and a cross-sectional thickness in a second direction orthogonal to the first direction less than the minimum feature length.

36. The method of claim 34, wherein forming a fin of amorphous semiconductor material on a crystalline substrate includes forming a pillar of amorphous silicon on a crystalline silicon substrate.

37. The method of claim 34, wherein forming the surrounding gate insulator includes forming a silicon oxide.

38. The method of claim 34, wherein forming a surrounding gate includes forming a polysilicon gate.

39. The method of claim 34, further comprising recessing the surrounding gate such that the surrounding gate has a height less than a height of the fin.

40. The method of claim 34, further comprising forming the first source/drain region with a P+ region at a first end of the fin and forming the second source/drain region with an N+ region at a second end of the fin.

41. The method of claim 40, wherein the first source/drain region is beneath the second source/drain region, and a channel region is vertically oriented between the first and second source/drain regions.

42. A transistor, comprising:
a crystalline substrate;
a crystalline semiconductor fin on the substrate, the semiconductor fin having a cross-sectional dimension that is less than a minimum feature size, wherein the fin provides a vertically-oriented channel between a lower source/drain region of a first conductivity type and an upper source/drain region of a second conductivity type;
a gate insulator formed around the fin; and
a surrounding gate formed around and separated from the fin by the gate insulator.

43. The transistor of claim 42, wherein the crystalline substrate is a silicon wafer.

44. The transistor of claim 42, wherein the gate insulator includes silicon oxide.

45. The transistor of claim 42, wherein the gate includes polysilicon.

46. The transistor of claim 42, wherein the gate includes metal.

47. The transistor of claim 42, wherein the lower source/drain region has an P+ conductivity and the upper source/drain region has an N+ conductivity.

48. The transistor of claim 47, further comprising a P+ conduction line formed in the substrate and connected to the lower source/drain region.

49. A method for forming a transistor, comprising:
forming a fin from a crystalline substrate;
forming a first source/drain region of a first conductivity type in the substrate beneath the fin;
forming a surrounding gate insulator around the fin;
forming a surrounding gate around the fin and separated from the fin by the surrounding gate insulator; and
forming a second source/drain region of a second conductivity type in a top portion of the fin.

50. The method of claim 49, wherein the first source/drain region has an P+ conductivity and the second source/drain region has an N+ conductivity.

51. The method of claim 50, further comprising a P+ conduction line formed in the substrate and connected to the first source/drain region.

52. The method of claim 49, wherein the fin has a cross-sectional thickness in a first direction corresponding to a minimum feature length and a cross-sectional thickness in a second direction orthogonal to the first direction less than the minimum feature length.

53. The method of claim 49, wherein forming a fin from a crystalline substrate includes forming a fin from a crystalline silicon substrate.

54. The method of claim 49, wherein forming a fin from a crystalline substrate includes etching the crystalline substrate to form the fin.

55. The method of claim 49, wherein forming a first source/drain region in the substrate beneath the fin includes implanting a dopant in a trench adjacent to the substrate and diffusing the dopant underneath the fin.

56. The method of claim 55, wherein diffusing includes diffusing the dopant into a bottom portion of the fin.

57. The method of claim 49, wherein forming a surrounding gate insulator includes forming a silicon oxide.

58. The method of claim 49, wherein forming a surrounding gate includes forming a polysilicon gate.

59. The method of claim 49, further comprising recessing the surrounding gate such that the surrounding gate has a height less than a height of the fin.

60. The method of claim 49, further comprising forming a gate contact adjacent to and in contact with the surrounding gate.

61. The method of claim 49, further comprising forming at least one gate line adjacent to and in contact with the surrounding gate.

62. The method of claim 61, wherein forming at least one gate line adjacent to and in contact with the surrounding gate includes forming a first gate line adjacent to and in contact with a first side the surrounding gate and a second gate line adjacent to and in contact with a second side of the surrounding gate, the first and second sides being positioned on opposing sides of the fin.

63. The method of claim 61, wherein the fin has a rectangular footprint with a short side and a long side, wherein forming at least one gate line adjacent to and in contact with the surrounding gate includes forming a gate line to contact the surrounding gate on the long side.

64. The method of claim 61, wherein the fin has a rectangular footprint with a short side and a long side, wherein forming at least one gate line adjacent to and in contact with the surrounding gate includes forming a gate line to contact the surrounding gate on the short side.

65. The method of claim 49, wherein forming a surrounding gate includes forming a polysilicon surrounding gate.

66. A transistor, comprising:
a crystalline substrate, with trenches etched therein to form a crystalline semiconductor fin from the substrate, the fin having a cross-sectional dimension that is less than a minimum feature size;
a first source/drain region of a first conductivity type formed in the crystalline substrate at a bottom of the fin, and a second source/drain region of a second conductivity type formed in a top portion of the fin to define a vertically-oriented channel region in the fin between the first and second source/drain regions;
a gate insulator formed around the fin; and
a surrounding gate formed around and separated from the fin by the gate insulator.

67. The transistor of claim 66, wherein the crystalline substrate includes silicon.

68. The transistor of claim 66, wherein the crystalline substrate is a crystalline silicon wafer.

69. The transistor of claim 66, wherein the surrounding gate insulator includes silicon oxide.

70. The transistor of claim 66, wherein the surrounding gate includes polysilicon.

71. The transistor of claim 66, wherein the surrounding gate includes metal.
